(19) United States
(12) Patent Application Publication
(10) Pub. No.: US 2005/0275061 A1
(43) Pub. Date: Dec. 15, 2005

(54) Semiconductor device having inductor

(75) Inventor: Tatsuya Ohguro, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 10/964,805

(22) Filed: Oct. 14, 2004

(30) Foreign Application Priority Data
Jun. 11, 2004 (JP) 2004-174390

(51) Int. Cl. H01L 23/552

(52) U.S. Cl. 257/531

(57) ABSTRACT

A semiconductor device includes a first chip having an inductor, a second chip stacked on the first chip and having a conductive layer, and a first magnetic shielding layer formed between the first and second chips.

### CROSS-REFERENCE TO RELATED APPLICATIONS

This application is based upon and claims the benefit of priority from the prior Japanese Patent Application No. 2004-17439, filed Jun. 11, 2004, the entire contents of which are incorporated herein by reference.

### BACKGROUND OF THE INVENTION

1. Field of the Invention

The present invention relates to a semiconductor device having an inductor.

2. Description of the Related Art

Recently, it is more and more required to reduce the areas of chips used in cell phones. This is because it is required to reduce the size of cell phones and at the same time improve the performance and increase the number of functions. To meet these requirements, the SIP (System In Package) technology, in which chips are stacked by decreasing their film thickness, is being studied.

Unfortunately, this SIP technology poses the problem of interference because the distance between circuits is decreased when chips are thinned. Especially when a chip having an inductor is stacked on another chip, if an interconnection of the other chip is present near this inductor, an induced current flows through the interconnection due to the influence of a magnetic field generated by the inductor. As a consequence, the Q value of the inductor decreases.

Prior art reference information related to the invention of this application is as follows. [Patent reference 1] Jpn. Pat. Appln. KOKAI Publication No. 2002-16209

### BRIEF SUMMARY OF THE INVENTION

A semiconductor device according to an aspect of the present invention comprises a first chip having an inductor, a second chip stacked on the first chip and having a conductive layer, and a first magnetic shielding layer formed between the first and second chips.

### BRIEF DESCRIPTION OF THE SEVERAL VIEWS OF THE DRAWING

FIG. 1 is a schematic sectional view showing a semiconductor device having an SIP structure according to the first embodiment of the present invention;

FIG. 2 is a plan view showing the relationship between the outer diameter of an inductor and the size of a shielding layer in the first embodiment of the present invention;

FIGS. 3 to 8 are sectional views showing the fabrication steps of the semiconductor device having the SIP structure according to the first embodiment of the present invention;

FIG. 9A is a TEM photograph showing a structure in which a shielding layer is deposited on a thin-film substrate in the first embodiment of the present invention;

FIG. 9B is a TEM photograph showing a region enclosed with the solid lines in FIG. 9A in an enlarged scale;

FIG. 10 is a view showing the result of EPMA analysis of the composition ratio of the shielding layer shown in FIGS. 9A and 9B;

FIG. 11 is a graph showing the relationship between the Fe content and resistivity when the shielding layer according to the first embodiment of the present invention is formed by an NiFe film;

FIG. 12 is a graph showing the dependence of the Q value of the inductor upon the frequency when the film thickness of the shielding layer according to the first embodiment of the present invention changes;

FIG. 13A is a schematic sectional view of a semiconductor device having an SIP structure according to the first embodiment of the present invention when no shielding layer is formed;

FIG. 13B is a schematic sectional view of a semiconductor device having an SIP structure according to the first embodiment of the present invention when a shielding layer is formed;

FIG. 14A is a graph showing the dependence of the Q value of the inductor upon the frequency in the first embodiment of the present invention when no shielding layer is formed;

FIG. 14B is a graph showing the dependence of the Q value of the inductor upon the frequency in the first embodiment of the present invention when a shielding layer is formed;

FIG. 15 is a graph which is used to explain the effect of the semiconductor device according to the first embodiment of the present invention, and which shows the relationship between the film thickness of a chip by which the Q value of the inductor decreases and the outer diameter of an inductor;

FIG. 16 is a graph which is used to explain the effect of the semiconductor device according to the first embodiment of the present invention, and which shows the relationship between the number of chips stacked in a space 500 μm high and the film thickness of a silicon substrate;

FIG. 17 is a schematic sectional view showing a semiconductor device having an SIP structure according to the second embodiment of the present invention;

FIGS. 18 to 23 are sectional views showing the fabrication steps of the semiconductor device having the SIP structure according to the second embodiment of the present invention;

FIG. 24 is a sectional view showing a packaged semiconductor device according to each embodiment of the present invention;

FIG. 25 is a sectional view showing a semiconductor device according to each embodiment of the present invention, in which first and second chips are adhered by an adhesive containing a magnetic material;

FIG. 26 is a sectional view showing a semiconductor device according to each embodiment of the present invention, in which a shielding layer is also formed on a second chip;

FIG. 27 is a sectional view showing a semiconductor device according to each embodiment of the present invention, in which a shielding layer is partially formed on the lower surface of a first chip;

FIG. 28 is a sectional view showing a semiconductor device according to each embodiment of the present invention, in which a shielding layer is formed around an inductor; and

FIGS. 29 and 30 are sectional views each showing a semiconductor device according to each embodiment of the present invention, in which four chips are stacked.

### DETAILED DESCRIPTION OF THE INVENTION

Embodiments of the present invention will be described below with reference to the accompanying drawing. In the following explanation, the same reference numerals denote the same parts throughout the drawing. For the sake of descriptive convenience, inductors and chips are schematically illustrated in the drawing, so the shapes, film thicknesses, sizes, and the like are not to scale ones in some cases.

### FIRST EMBODIMENT

In the first embodiment, a chip having an inductor for use in a high-frequency circuit or the like is stacked on another chip using the SIP (System In Package) technology, and a shielding layer for intercepting lines of magnetic force generated from the inductor is formed between the two chips.

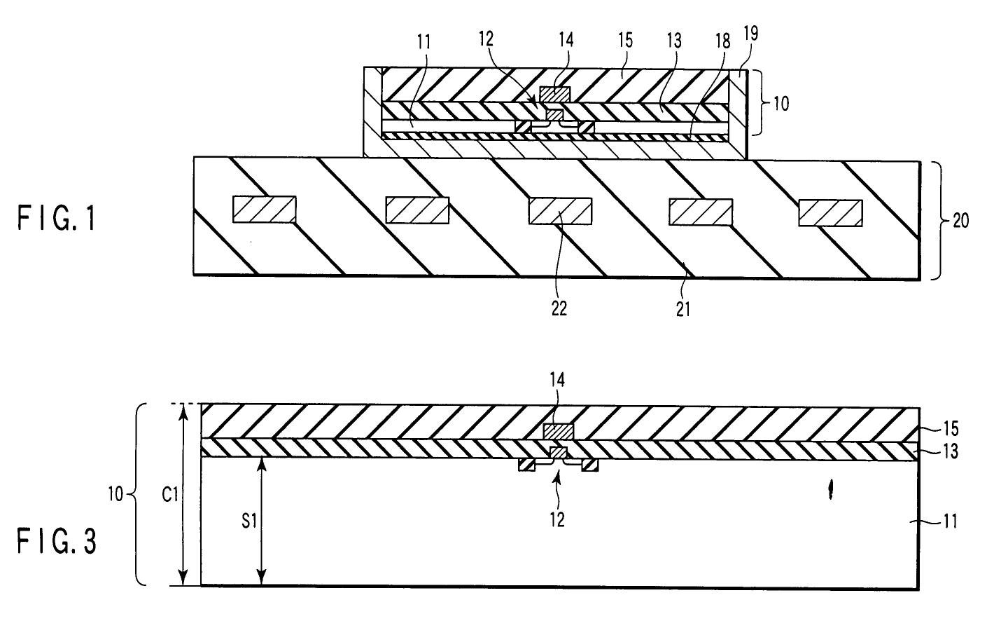

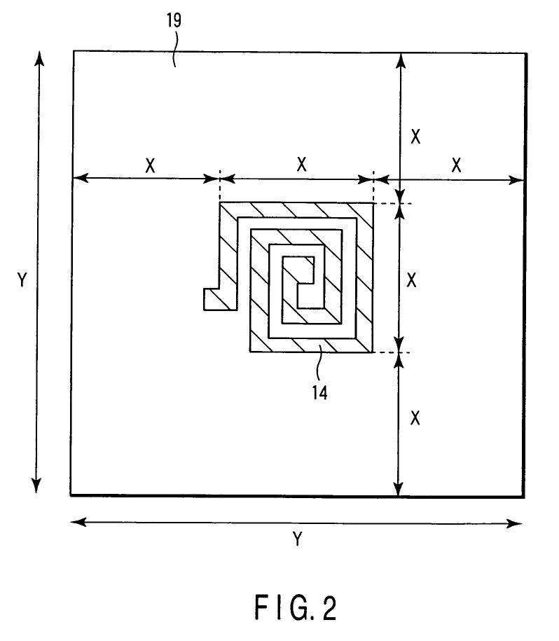

FIG. 1 is a schematic sectional view showing a semiconductor device having an SIP structure according to the first embodiment of the present invention. FIG. 2 is a plan view for explaining the relationship between the outer diameter of the inductor and the size of the shielding layer in the first embodiment of the present invention. This semiconductor device having the SIP structure according to the first embodiment will be explained below.

As shown in FIG. 1, first and second chips 10 and 20 are stacked using the SIP technology. The first chip 10 includes a semiconductor substrate 11, an element 12 formed on the surface of the semiconductor substrate 11, and an inductor 14 formed above the semiconductor substrate 11. The second chip 20 includes conductive layers 22. An insulating film 18 is formed on the lower surface of the first chip 10 (the lower surface of the semiconductor substrate 11). A shielding layer 19 made of a magnetic material is formed on that surface of the insulating film 18, which is opposite to the surface facing the first chip 10, and on the side surfaces of the first chip 10. That is, to suppress the adverse effect which lines of magnetic force generated from the inductor 14 have on the conductive layers 22, the shielding layer 19 is formed between the first and second chips 10 and 20, more specifically, between the inductor 14 and conductive layers 22.

As the magnetic material of the shielding layer 19, it is desirable to use, e.g., Ni, Fe, Co, or a material containing at least one of Ni, Fe, and Co. The material containing at least one of Ni Fe, and Co includes an alloy containing at least one of Ni, Fe, and Co, and an alloy (e.g., NiFe or CoFe) which is a combination of Ni, Fe, and Co.

The material of the shielding layer 19 may also be an oxide-based material, such as magnetite, CrO2, or RXMnO3-y (R; rare-earth element, X; Ca, Ba, or Sr), having high spin polarizability, or a Heusler alloy such as NiMnSb or PtMnSb. Note that the magnetic material of the shielding layer 19 may also contain a non-magnetic element, e.g., Ag, Cu, Au, Al, Mg, Si, Bi, Ta, B, C, 0, N, Pd, Pt, Zr, Ir, W, Mo, or Nb, provided that the magnetic characteristics are not lost.

The inductor 14 is, e.g., a planar spiral coil (FIG. 2), and made of a low-resistance material such as Al, Cu, or Au.

The conductive layers 22 are, e.g., metal interconnections, gate electrodes of transistors, or contacts, and made of Al, Cu, W, polysilicon, or the like.

The element 12 is, e.g., a MOS transistor. The minimum gate length of the gate electrode of this MOS transistor is, e.g., 110 nm or less. Note that the element 12 is not limited to a transistor, and it is of course also possible to form an interconnection, contact, capacitor, or the like in the first chip 10.

The insulating film 18 is made of, e.g., a silicon oxide film. Although the insulating film 18 is not always necessary, the shielding layer 19 is desirably formed on the lower surface of the semiconductor substrate 11 not directly but via the insulating film 18. This is so because adjacent elements may conduct each other if the conductive shielding layer 19 is formed without forming the insulating film 18, but the insulating film 18 does not allow any adjacent elements to conduct each other, and prevents noise from entering any adjacent element. To thus impart the conduction preventing function to the insulating film 18, the insulating film 18 desirably has a film thickness of, e.g., 3 nm or more.

As shown in FIG. 2, to intercept lines of magnetic force generated from the inductor 14, the area of the shielding layer 19 is desirably larger than the area in which the inductor 14 is present. That is, the area of the shielding layer 19 desirably extends outward from the outermost line of the inductor 14 by an amount equal to or larger than an outer diameter X of the inductor 14. In other words, a width Y of the shielding layer 19 is desirably three times the outer diameter X of the inductor 14 or more. That is, a line of magnetic force generated from the outmost line of the inductor 14 presumably spreads outside the inductor 14 by about the outer diameter X of the inductor 14. Therefore, the area of the shielding layer 19 is so determined as to reliably intercept this outermost line of magnetic force. For example, when the outer diameter X of the inductor 14 is 100 to 400 μm, the width Y of the shielding layer 19 is preferably 300 to 1,200 μm.

FIGS. 3 to 8 are sectional views showing the fabrication steps of the semiconductor device having the SIP structure according to the first embodiment of the present invention. The method of fabricating the semiconductor device according to the first embodiment will be described below. In this method, chips are divided by using half-cut dicing.

First, as shown in FIG. 3, a first chip 10 is formed as follows. An element 12 such as a MOS transistor is formed on a semiconductor substrate (e.g., a silicon substrate) 11, and an insulating film (e.g., a silicon oxide film) 13 is formed on the semiconductor substrate 11 and element 12. Then, an inductor 14 is formed on the insulating film 13, and an insulating film (e.g., a silicon oxide film) 15 is formed on the insulating film 13 and inductor 14. A film thickness C1 of the first chip 10 thus formed is, e.g., about 750 μm, and a film thickness S1 of the semiconductor substrate 11 is, e.g., about 747 μm.

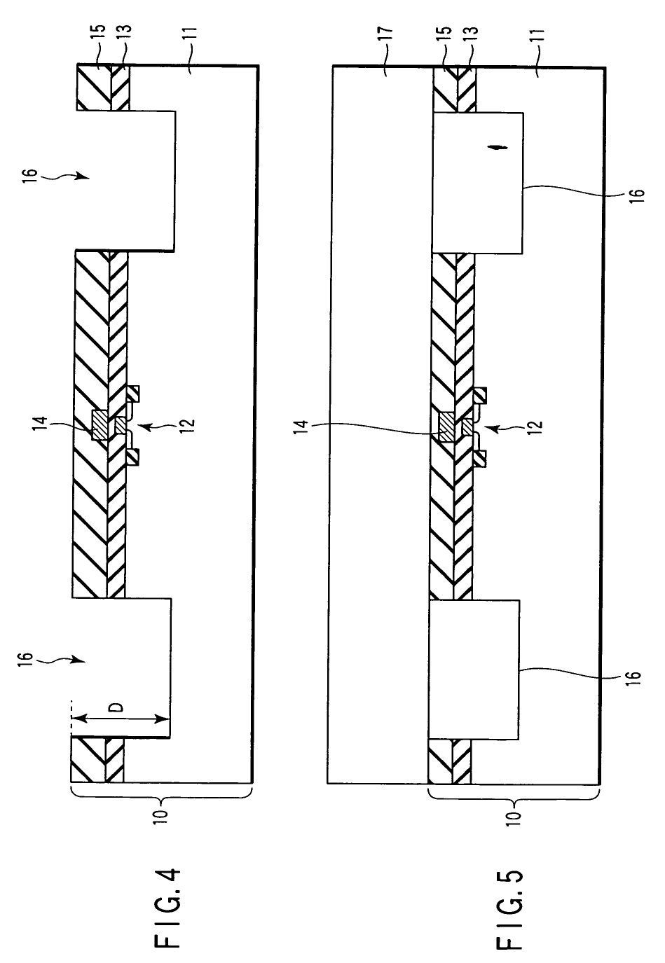

Subsequently, as shown in FIG. 4, the first chip 10 is processed by anisotropic etching such as RIE (Reactive Ion Etching) to form trenches 16. The trenches 16 extend from the surface of the chip 10 (the surface of the insulating film 15) to the interior of the semiconductor substrate 11, and have a depth D of, e.g., about 50 μm.

As shown in FIG. 5, a protective tape 17 is adhered on the surface of the chip 10 (the surface of the insulating film 15).

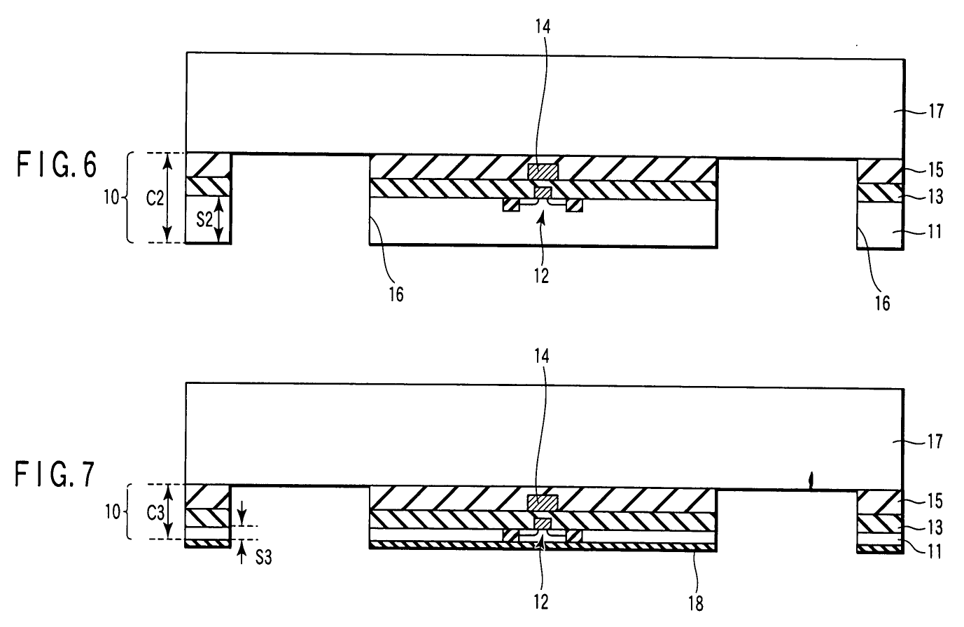

As shown in FIG. 6, the lower surface of the chip 10 (the lower surface of the semiconductor substrate 11) where the protective tape 17 is not present is ground by, e.g., a grinder. This grinding decreases a film thickness C2 of the first chip 10 to, e.g., about 23 μm, and a film thickness S2 of the semiconductor substrate 11 to, e.g., about 20 μm. Since, therefore, the lower surface of the chip 10 is ground to the depth D of the trenches 16 or more, the bottom surfaces of the trenches 16 are opened to divide the first chip 10.

As shown in FIG. 7, to decrease the etching rate, grinding is switched to dry etching or wet etching to further etch the lower surface of the semiconductor substrate 11. Consequently, a film thickness C3 of the first chip 10 further decreases to, e.g., about 4.6 μm, and a film thickness S3 of the semiconductor substrate 11 further decreases to, e.g., about 1.6 μm.

Although this etching can be either isotropic etching or anisotropic etching, anisotropic etching is more desirable. This is so because the uniformity of thinning of the semiconductor substrate 11 can be held better by anisotropic etching than by isotropic etching.

When this etching is completed, an oxide film (silicon oxide film) 18 is naturally formed on the lower surface of the semiconductor substrate 11. If the insulation properties of the insulating film 18 are unsatisfactory, the insulating film 18 may also be oxidized by, e.g., radiating an oxygen plasma.

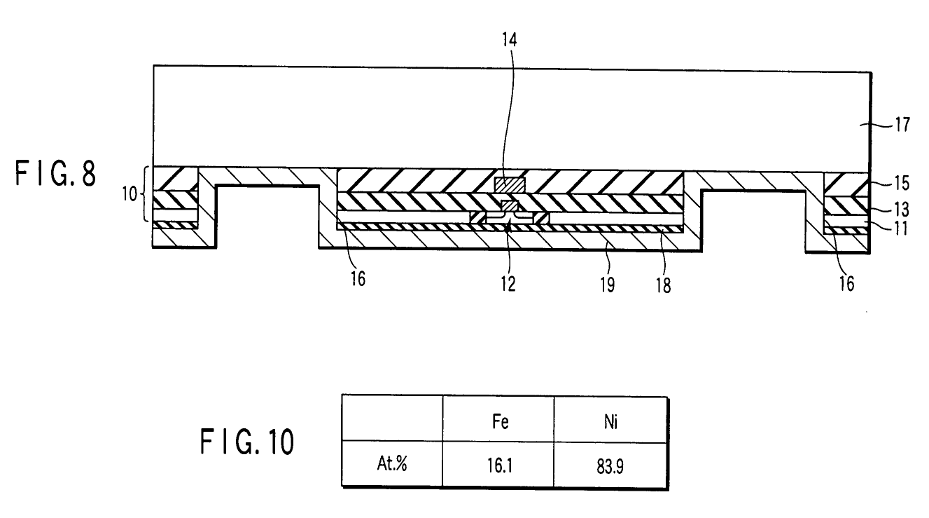

As shown in FIG. 8, a shielding layer 19 made of a magnetic material is deposited by using, e.g., sputtering, on the insulating film 18, on the protective tape 17, and on the side surfaces of the trenches 16. Although the shielding layer 19 can also be formed by, e.g., CVD (Chemical Vapor Deposition), sputtering is more desirable. This is so because the protective tape 17 melts more hardly by sputtering as low-temperature processing than by CVD as high-temperature processing, and the shielding layer 19 made of a magnetic material is deposited more easily by sputtering than by CVD.

Then, as shown in FIG. 1, the first chips 10 are cut one after another by dicing or the like. A second chip 20 having conductive layers 22 in an insulating film 21 is prepared and adhered to the first chip 10. More specifically, the shielding layer 19 formed on the lower surface of the semiconductor substrate 11 is adhered to the second chip 20, so that the shielding layer 19 is present between the inductor 14 and conductive layers 22. After that, the protective tape 17 is peeled. In this manner, an SIP structure in which the two chips 10 and 20 are stacked is completed.

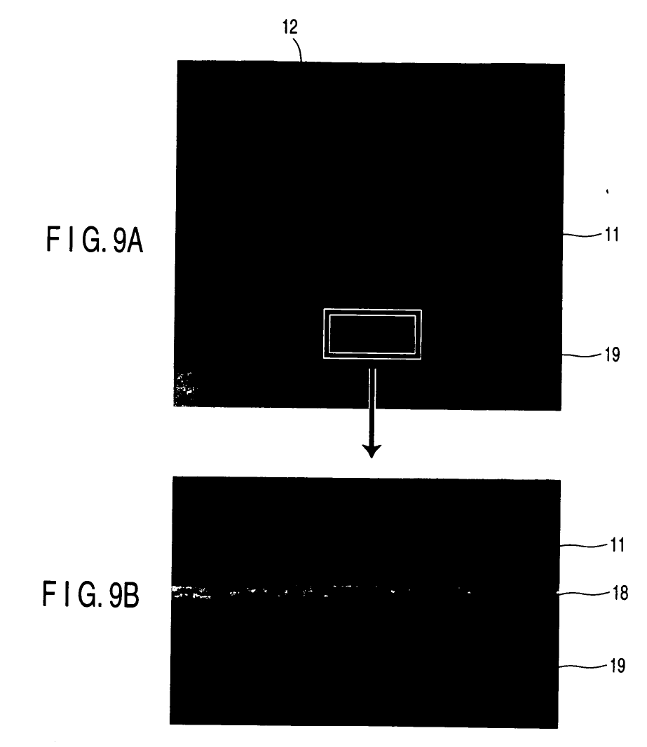

FIGS. 9A and 9B are TEM (Transmission Electron Microscope) photographs after a shielding layer was deposited on a thin-film substrate according to the first embodiment of the present invention. FIG. 10 shows the result of EPMA (Electron Probe Micro Analysis) of the composition ratio of the shielding layer shown in FIGS. 9A and 9B. In the above-mentioned fabrication method, an insulating film is formed between a semiconductor substrate and shielding layer. This will be described below.

FIG. 9A is a TEM photograph of the state (the step shown in FIG. 8) in which a shielding layer 19 was deposited on the lower surface of a thin-film semiconductor substrate 11. When a region enclosed with the solid lines in FIG. 9A was enlarged, as shown in FIG. 9B, an insulating film 18 was formed between the lower surface of the semiconductor substrate 11 and the shielding layer 19. In this experiment, the semiconductor substrate 11 was ground to a thickness of 1.7 μm, and the 50-nm thick shielding layer 19 made of an NiFe film was deposited on the lower surface of the semiconductor substrate 11. In this case, an 11-nm thick insulating film 18 was formed. Accordingly, although the NiFe shielding layer 19 is a metal layer, conduction between the shielding layer 19 and semiconductor substrate 11 can be prevented because the insulating film 18 is formed between the shielding layer 19 and semiconductor substrate 11.

In this experiment, the composition ratio of the shielding layer 19 made of an NiFe film was analyzed by EPMA. Consequently, as shown in FIG. 10, Fe was 16.1%, and Ni was 83.9%.

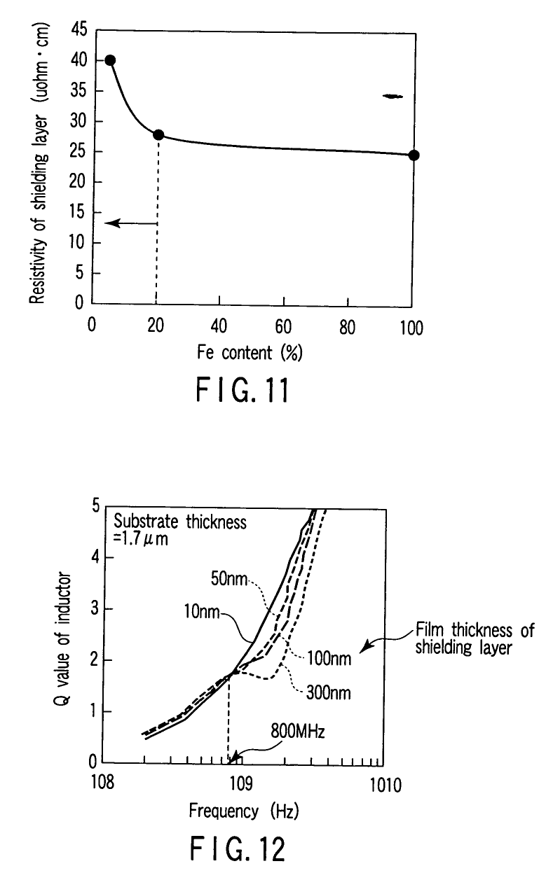

FIG. 11 is a graph showing the relationship between the Fe content and resistivity when the shielding layer according to the first embodiment of the present invention is formed by an NiFe film. A desirable Fe content when the shielding layer is formed by an NiFe film will be explained below.

As shown in FIG. 11, even when the Fe content in the shielding layer 19 reduces from 100% to about 20%, the resistivity of the shielding layer 19 remains almost the same. However, when the Fe content becomes smaller than 20%, the resistivity of the shielding layer 19 gradually rises.

An induced electromotive force is generated below the inductor 14 by a magnetic field generated from the inductor 14. However, since induced current=induced electromotive force/resistance value, the induced current generated in the conductive layer 22 easily flows if the resistance of the shielding layer 19 is low. Therefore, the resistance of the shielding layer 19 is preferably as high as possible. For this reason, when the shielding layer 19 is formed by an NiFe film, the Fe content of the NiFe film is preferably 20% or less.

From the foregoing, the shielding layer 19 is desirably formed not by a conductive magnetic material but by an insulating magnetic material. An example of the conductive magnetic material is a permalloy-based magnetic material, and an example of the insulating magnetic material is a ferrite-based magnetic material. Note that when the shielding layer 19 is formed by a conductive magnetic material, the metal content is preferably, e.g., 50% or less.

FIG. 12 shows the dependence of the Q value of the inductor upon the frequency when the film thickness of the shielding layer according to the first embodiment of the present invention changes. A desirable film thickness of the shielding layer will be explained below. The results shown in FIG. 12 were obtained when the film thickness of the semiconductor substrate was 1.7 μm, and the shielding layer was formed by an NiFe film.

As shown in FIG. 12, the film thickness of the shielding layer 19 was changed to 10, 50, 100, and 300 nm. When the film thickness was 10 or 50 nm, the Q value of the inductor 14 increased as the frequency was raised. When the film thickness was 100 nm, the Q value of the inductor 14 slightly decreased at about 800 MHz. When the film thickness was 300 nm, the Q value of the inductor 14 largely decreased at about 800 to 1,200 MHz. This is so probably because when the film thickness of the shielding layer 19 made of an NiFe film increased, the resistance value of the shielding layer 19 decreased, and this allowed an induced current to flow through the conductive layers 22 more easily. Accordingly, the film thickness of the shielding layer 19 is preferably as small as possible. When the shielding layer 19 is formed by an NiFe film, the thickness of this NiFe film is desirably, e.g., less than 50 nm. To obtain the effect of intercepting lines of magnetic force, however, the film thickness of the shielding layer 19 is desirably 1 nm or more.

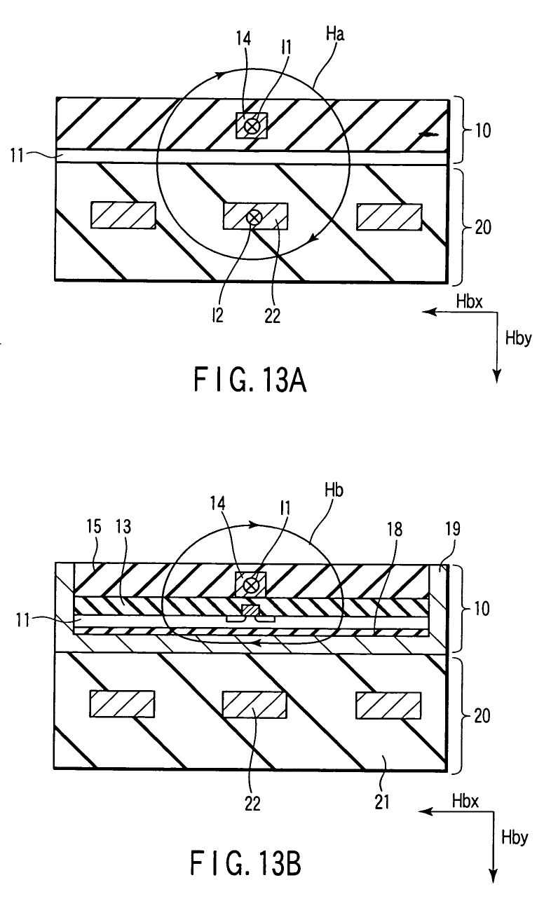

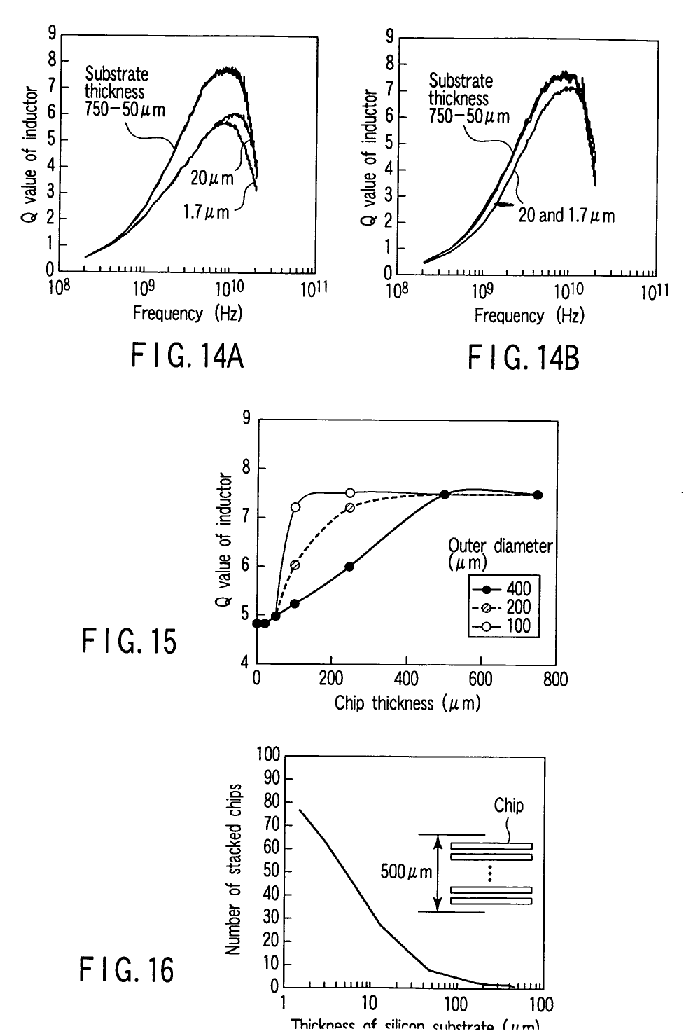

FIGS. 13A and 13B are schematic sectional views each showing a semiconductor device having an SIP structure according to the first embodiment of the present invention. FIG. 13A shows a device having no shielding layer, and FIG. 13B shows a device having a shielding layer. FIGS. 14A and 14B are graphs each showing the dependence of the Q value of an inductor upon the frequency in the first embodiment of the present invention. FIG. 14A shows a device having no shielding layer, and FIG. 14B shows a device having a shielding layer. The influence a magnetic field (a line of magnetic force) generated from the inductor has on the conductive layer and the Q value of the inductor when the film thickness of the substrate is decreased will be explained below for each of the device having the shielding layer formed on the lower surface of the substrate and the device having no such shielding layer.

First, the device having no shielding layer will be described below with reference to FIGS. 13A and 14A.

As shown in FIG. 13A, when an electric current I1 flows through the inductor 14, a magnetic field Ha is generated by the electric current I1. The magnetic field Ha extends to the vicinity of the conductive layer 22 of the second chip 20. As a consequence, an induced current I2 is generated in the conductive layer 22 by the magnetic field Ha.

The thinner the semiconductor substrate 11, the shorter the distance between the inductor 14 and conductive layer 22, so the more easily the conductive layer 22 is influenced by the magnetic field Ha, and the larger the induced current I2.

As shown in FIG. 14A, therefore, as the thickness of the semiconductor substrate 11 is decreased, the energy loss is increased by the induced current I2, so the Q value of the inductor 14 gradually decreases.

The device having the shielding layer will be explained below with reference to FIGS. 13B and 14B.

As shown in FIG. 13B, when the electric current I1 flows through the inductor 14, a magnetic field Hb is generated by the electric current I1. However, when the magnetic field Hb passes through the shielding layer 19, the magnetization of the shielding layer 19 increases a field component Hbx in a direction parallel to the surface of the shielding layer 19 (the lateral direction of the paper). This decreases a field component Hby in a direction perpendicular to the surface of the shielding layer 19 (the longitudinal direction of the paper). Consequently, the magnetic field Hb is shielded by the shielding layer 19, and this prevents the magnetic field Hb from extending toward the second chip 20. In other words, even when lines of magnetic force are generated from the inductor 14 in the first chip 10, it is possible by the shielding effect of the shielding layer 19 to reduce the number of lines of magnetic force which invade the conductive layer 22 in the second chip 20. So, the induced current generated in the conductive layer 22 can be reduced.

Accordingly, even when the thickness of the semiconductor substrate 11 is decreased to shorten the distance between the inductor 14 and conductive layer 22, the increase in induced current generated in the conductive layer 22 can be suppressed by the shielding effect of the shielding layer 19.

As shown in FIG. 14B, therefore, even when the film thickness of the semiconductor substrate 11 is decreased from the range of 50 to 750 μm to 20 or 1.7 μm, the increase in energy loss caused by the induced current can be suppressed by the shielding layer 19. Therefore, the decrease in Q value of the inductor 14 can be suppressed.

Note that even if the invasion of lines of magnetic field to the conductive layer 22 cannot be prevented 100%, the decrease in Q value can be well suppressed as shown in FIG. 14B when the invasion of lines of magnetic force is suppressed.

The following effects can be obtained by the first embodiment.

(a) The shielding layer 19 made of a magnetic material is formed between the first and second chips 10 and 20 (between the inductor 14 and conductive layer 22). This makes it possible to prevent a magnetic field generated from the inductor 14 from reaching the conductive layer 22 by the shielding layer 19. Since the generation of an induced current in the conductive layer 22 can be prevented, the decrease in Q value of the inductor 14 can be suppressed. In addition, the generation of substrate noise can be suppressed because an induced electromotive force generated in the semiconductor substrate 11 below the inductor 14 can be suppressed.

(b) FIG. 15 shows the relationship between the film thickness of the chip by which the Q value of the inductor 14 decreases and the outer diameter of the inductor 14 when no shielding layer is formed. As shown in FIG. 15, when the outer diameter of the inductor 14 is 400 μm, the Q value starts decreasing from a chip film thickness of about 500 μm. When the outer diameter of the inductor 14 is 200 μm, the Q value starts decreasing from a chip film thickness of about 200 μm. When the outer diameter of the inductor 14 is 100 μm, the Q value starts decreasing from a chip film thickness of about 100 μm. That is, the outer diameter of the inductor 14 and the film thickness of the chip by which the Q value decreases are substantially equal.

Although the outer diameter of the generally used inductor 14 is 100 to 400 μm, it is possible to use a thin-film chip thinner than the outer diameter of the inductor 14 in an SIP structure. However, as indicated by the results shown in FIG. 15, to suppress the decrease in Q value, it is desirable to make the chip film thickness larger than the outer diameter of the inductor 14. As described above, when no shielding layer is formed, the film thickness of the chip is limited by the outer diameter of the inductor 14 in order to suppress the decrease in Q value.

By contrast, since the shielding layer 19 is formed in the first embodiment, the decrease in Q value can be suppressed by the shielding effect of the shielding layer 19 even when the chip is made thinner than the outer diameter of the inductor 14. In the first embodiment, therefore, the film thickness of the chip can be decreased without being limited by the outer diameter of the inductor 14. Accordingly, in an SIP structure, the number of stacked chips can be increased without being limited by the outer diameter of the inductor 14. In the first embodiment as described above, the film thickness of the chip 10 can be made smaller than the outer diameter of the inductor 14, i.e., the film thickness of the semiconductor substrate 11 can be made smaller than the outer diameter of the inductor 14.

(c) FIG. 16 shows the relationship between the number of chips stacked in a space 500 μm high and the film thickness of a silicon substrate. As shown in FIG. 16, the number of chips significantly increases when the film thickness of the silicon substrate is decreased. This also indicates that the chip thinning technique is very important.

Unfortunately, the conventional lower limit of the film thickness of a chip is presumably about 20 μm for the reasons explained below. First, when a silicon substrate is thinned by a grinder, the controllability of the film thickness of the silicon substrate is low, so film thickness variations of ±5 μm are present. Therefore, when a silicon substrate is thinned to 5 μm or less, portions where no chip is present are formed on the surface of a wafer, and this significantly reduces the yield. Also, when a grinder is used, the etching rate is high, so a silicon substrate is sometimes ground too much. This makes accurate control of the film thickness of the silicon substrate impossible. Furthermore, when a silicon substrate is ground by a grinder, the stress to chips is large, so the thinned chips easily break.

In the first embodiment, however, when etching is performed to thin the semiconductor substrate 11 (the steps shown in FIGS. 6 and 7), a grinder is switched to dry etching or wet etching having an etching rate lower than that of the grinder. Since this lowers the etching rate, the film thickness of the semiconductor substrate 11 can be easily controlled. Additionally, the stress to chips during etching can be suppressed, so the problem of chip break can be avoided. From the foregoing, chips can be thinned more easily than when they are thinned by using only a grinder, so the number of stacked chips can be increased. More specifically, the film thickness C3 of the chip 10 can be decreased to about 4.6 μm. This makes it possible to form a chip having a thickness of 20 μm or less, which is conventionally difficult to form.

### SECOND EMBODIMENT

In the second embodiment, an SOI (Silicon On Insulator) substrate is used instead of the conventional semiconductor substrate used in the first embodiment.

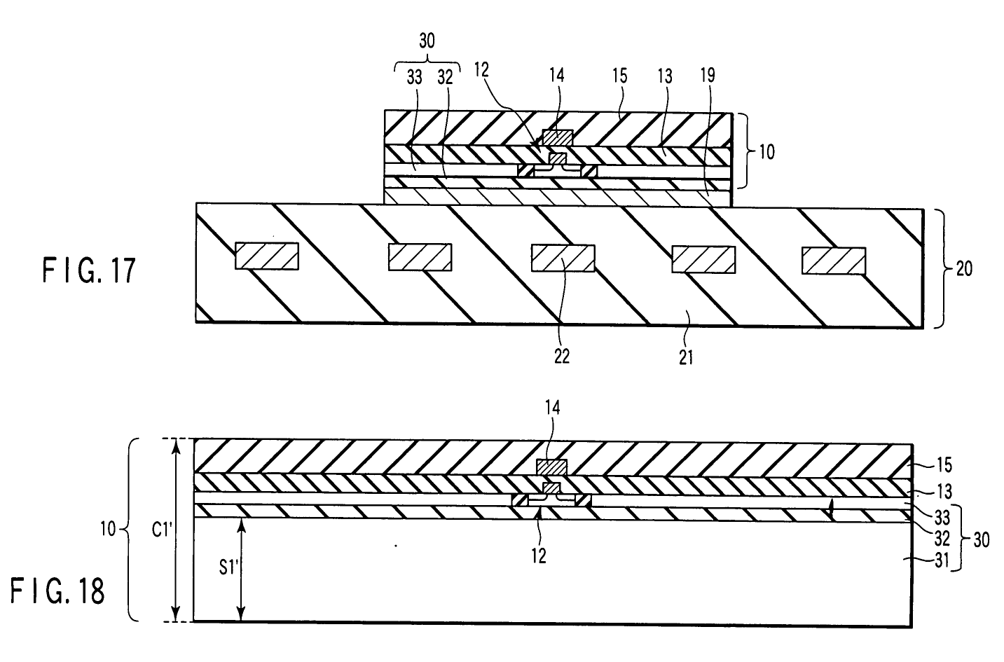

FIG. 17 is a schematic sectional view showing a semiconductor device having an SIP structure according to the second embodiment of the present invention. This semiconductor device according to the second embodiment will be described below.

As shown in FIG. 17, the main differences of the second embodiment from the first embodiment are that an SOI substrate 30 is used as a first chip 10, a buried insulating film 32 forming the SOI substrate 30 replaces the insulating film 18 shown in FIG. 1, and a shielding layer 19 is not present on the side surfaces of the first chip 10.

The SOI substrate 30 is made up of a semiconductor substrate 31, the buried insulating film 32, and a semiconductor layer 33. Referring to FIG. 17, however, the semiconductor substrate 31 is eliminated by grinding. Therefore, the shielding layer 19 is formed on the buried insulating film 32 forming the SOI substrate 30. The buried insulating film 32 functions as a layer which makes the semiconductor layer 33 and shielding layer 19 non-conductive.

Also, by executing a fabrication method to be described below, the shielding layer 19 is not formed on the side surfaces of the first chip 10, but formed only on the lower surface (the buried insulating film 32) of the first chip 10. The shielding effect can be improved when the shielding layer 19 is also formed on the side surfaces of the first chip 10 as in the first embodiment. However, it is possible to obtain a satisfactory shielding effect capable of suppressing the decrease in Q value even when the shielding layer 19 is formed only on the lower surface of the first chip 10 as in the second embodiment.

FIGS. 18 to 23 are sectional views showing the fabrication steps of the semiconductor device having the SIP structure according to the second embodiment of the present invention. The method of fabricating the semiconductor device according to the second embodiment will be described below. As in the first embodiment, chips are divided by using half-cut dicing.

First, as shown in FIG. 18, a first chip 10 is formed as follows. An element 12 such as a MOS transistor is formed on an SOI substrate 30 made up of a semiconductor substrate (e.g., a silicon substrate) 31, buried insulating film 32, and semiconductor layer 33, and an insulating film (e.g., a silicon oxide film) 13 is formed on the semiconductor substrate 31 and element 12. Then, an inductor 14 is formed on the insulating film 13, and an insulating film (e.g., a silicon oxide film) 15 is formed on the insulating film 13 and inductor 14. A film thickness C1′ of the first chip 10 thus formed is, e.g., about 755 μm, and a film thickness S1′ of the semiconductor substrate 31 is, e.g., about 750 μm.

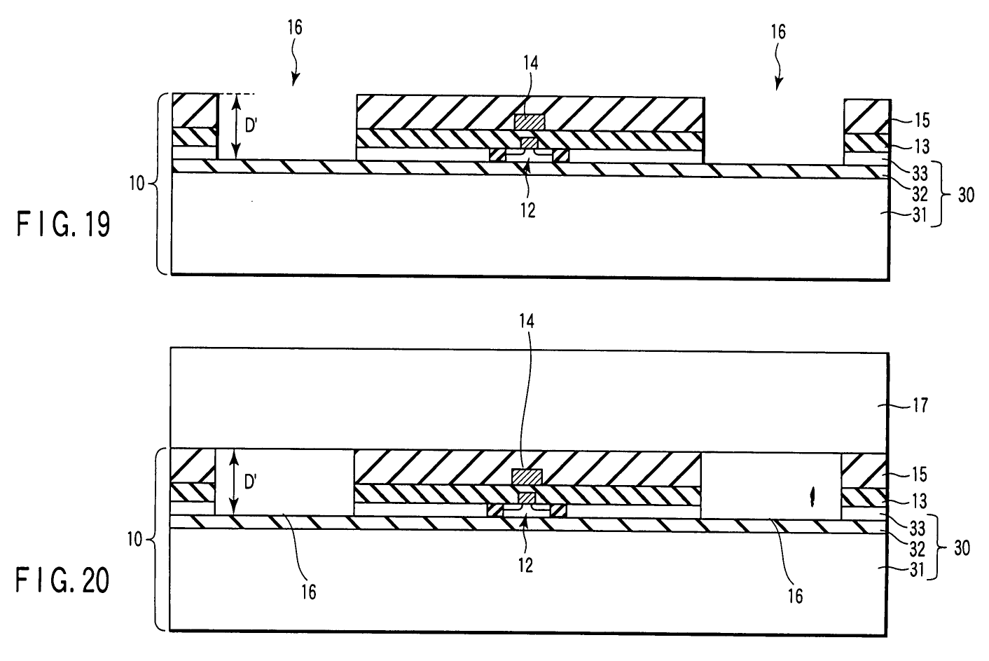

Subsequently, as shown in FIG. 19, the first chip 10 is processed by anisotropic etching such as RIE (Reactive Ion Etching) to form trenches 16. The trenches 16 extend from the surface of the chip 10 (the surface of the insulating film 15) to the buried insulating film 32, and have a depth D of, e.g., about 5 μm.

As shown in FIG. 20, a protective tape 17 is adhered on the surface of the chip 10 (the surface of the insulating film 15).

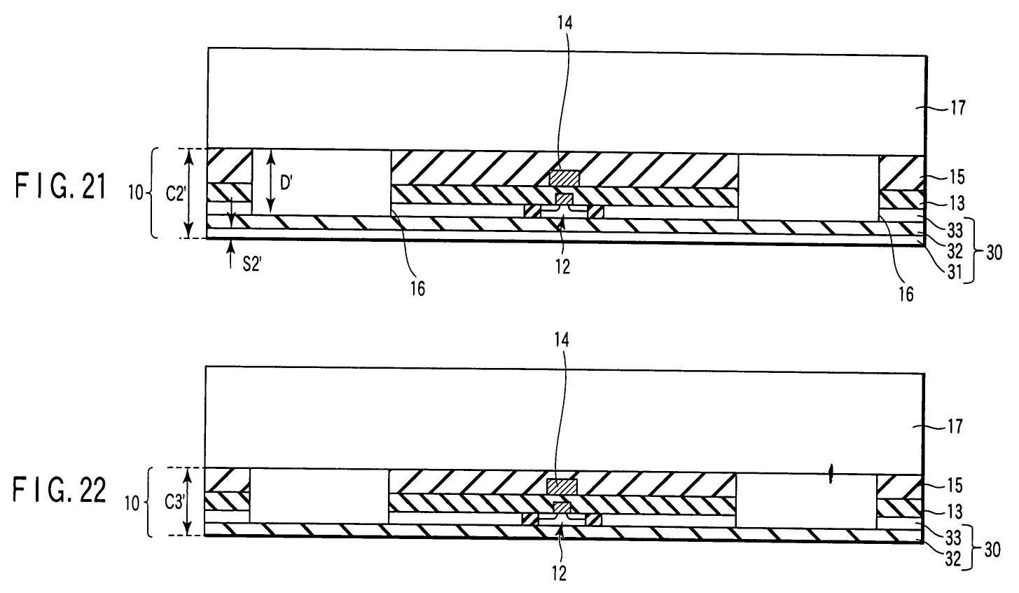

As shown in FIG. 21, the lower surface of the chip 10 (the lower surface of the semiconductor substrate 31) where the protective tape 17 is not present is ground by, e.g., a grinder, such that the semiconductor substrate 31 is not completely eliminated. This grinding decreases a film thickness C2′ of the first chip 10 to, e.g., about 25 μm, and a film thickness S2′ of the semiconductor substrate 31 to, e.g., about 20 μm.

In the step shown in FIG. 6 of the first embodiment, the lower surface of the chip 10 is ground to the depth D of the trenches 16 or more, so the bottom surfaces of the trenches 16 are opened to divide the first chip 10. By contrast, in the step shown in FIG. 20 of the second embodiment, the lower surface of the chip 10 is not ground to the depth D′ of the trenches 16, so the first chip 10 is not divided yet in this stage.

As shown in FIG. 22, to decrease the etching rate, grinding is switched to dry etching or wet etching to further etch the lower surface of the semiconductor substrate 31 until the buried insulating film 32 is exposed. Consequently, a film thickness C3′ of the first chip 10 further decreases to, e.g., about 5 μm.

In the step shown in FIG. 7 of the first embodiment, the oxide film (silicon oxide film) 18 is naturally formed on the lower surface of the semiconductor substrate 11. By contrast, in the step shown in FIG. 22 of the second embodiment, no natural oxide film is formed because the buried insulating film 32 is present.

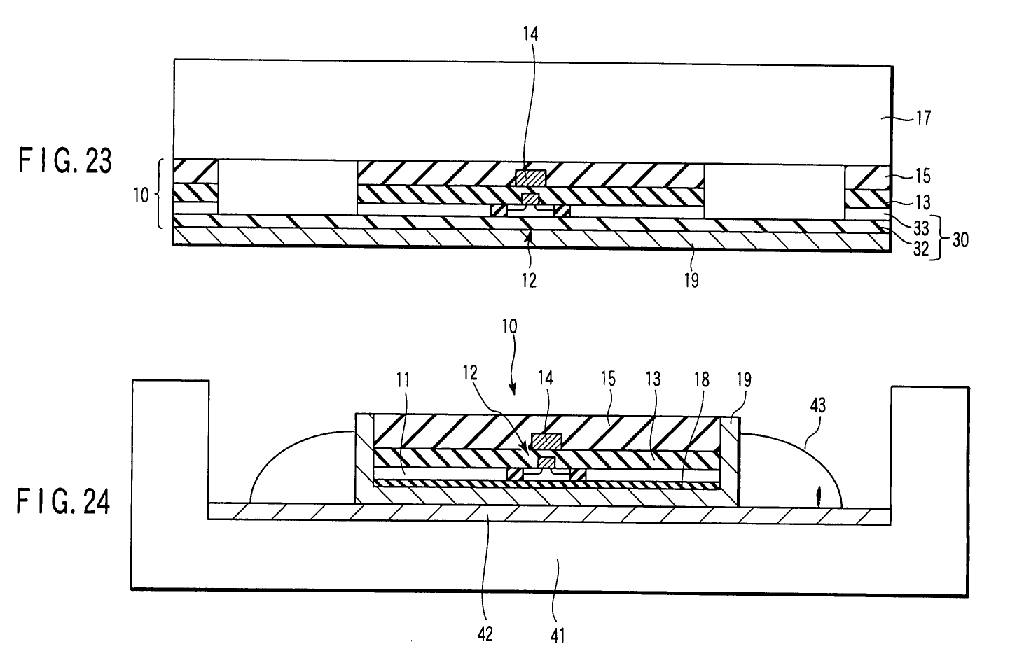

As shown in FIG. 23, a shielding layer 19 made of a magnetic material is deposited on the buried insulating film 32 by using, e.g., sputtering.

Then, as shown in FIG. 17, the first chips 10 are cut one after another by dicing or the like. A second chip 20 having conductive layers 22 in an insulating film 21 is prepared and adhered to the first chip 10. More specifically, the shielding layer 19 formed on the lower surface of the first chip 10 is adhered to the second chip 20, so that the shielding layer 19 is present between the inductor 14 and conductive layers 22. After that, the protective tape 17 is peeled. In this manner, an SIP structure in which the two chips 10 and 20 are stacked is completed.

In the second embodiment described above, it is possible to obtain not only the same effects as in the first embodiment but also the following effects.

First, when the trenches 16 are formed in the step shown in FIG. 19, etching can be controlled by using the buried insulating film 32 of the SOI substrate 30 as a stopper. This facilitates control of the depth D′ of the trenches 16.

Also, when the semiconductor substrate 31 is etched in the step shown in FIG. 22, the selective ratio of the semiconductor substrate 31 as a silicon substrate to the buried insulating film 32 as an oxide film is high, so etching can be stopped at the buried insulating film 32. Since this facilitates control of etching of the semiconductor substrate 31, it is possible to prevent etching from having an adverse effect on the semiconductor layer 33.

The present invention is not limited to the above embodiments but can be variously modified when practiced without departing from the spirit and scope of the invention.

(1) In each of the first and second embodiments, an SIP structure in which a plurality of chips are stacked is explained. However, the present invention is also applicable to a structure in which one chip is packaged. For example, as shown in FIG. 24, when a chip 10 is mounted on a conductor plate 42 formed in a package 41 and connected to the conductor plate 42 by wires 43, it is possible by the shielding effect of a shielding layer 19 to prevent lines of magnetic force generated from an inductor 14 from adversely affecting the conductor plate 42.

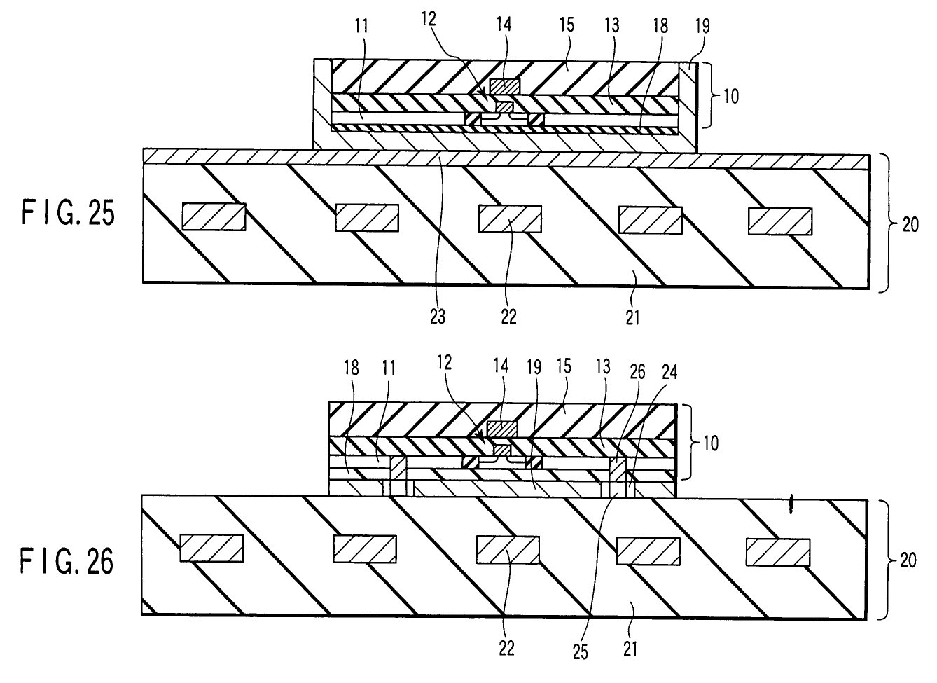

(2) As shown in FIG. 25, first and second chips 10 and 20 may also be adhered by an adhesive 51 containing a magnetic material. The adhesive 51 made of the magnetic material can further intercept lines of magnetic force.

(3) In each of the first and second embodiments, the shielding layer 19 is formed only on the first chip 10. However, as shown in FIG. 26, a shielding layer 23 made of a magnetic material may also be formed on that surface of a second chip 20, which faces a first chip 10. In this case, the effect of intercepting lines of magnetic force can be further increased.

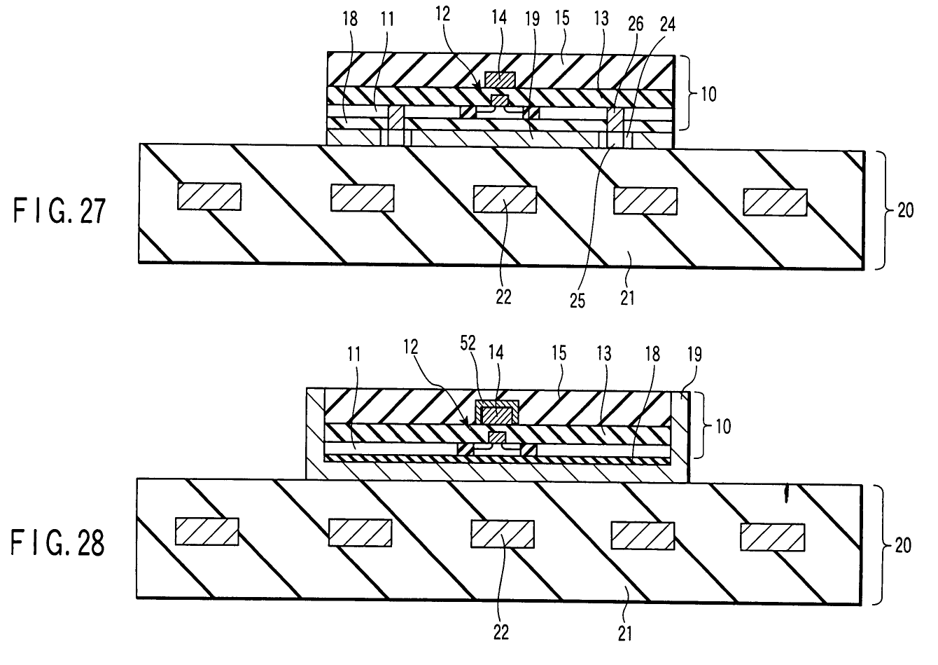

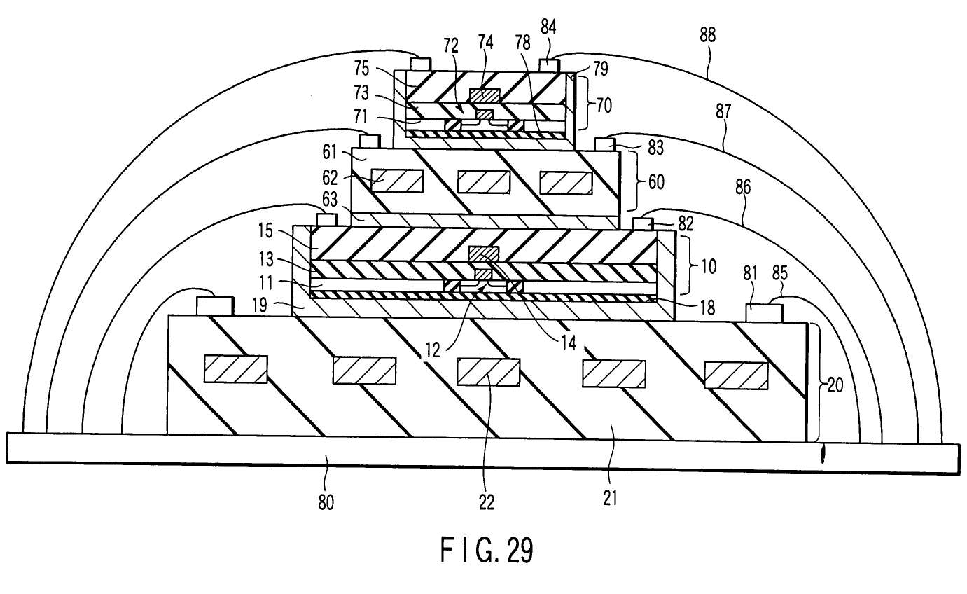

(4) The shielding layer 19 need not be formed on the entire lower surface of the first chip 10. As shown in FIG. 27, it is also possible to partially form a shielding layer 19 on the lower surface of a first chip 10. As a consequence, pads 25 of a second chip 20 can be extracted outside and arranged in gaps 24 of the shielding layer 19. The first and second chips 10 and 20 can be connected at the shortest distance by forming metal layers 26 through a semiconductor substrate 11 and insulating film 18 of the first chip 10, and connecting the metal layers 26 and pads 25. Accordingly, signal transmission delays and losses can be reduced in this structure shown in FIG. 27 because the signal lines between the first and second chips 10 and 20 are shortest, compared to a structure (e.g., FIG. 29) in which pads are formed on individual chips and signals are exchanged between the chips via bonding wires.

(5) A shielding layer made of a magnetic material may also be formed around the inductor 14. For example, as shown in FIG. 28, a shielding layer 52 made of a magnetic material may also be formed on the upper surface and side surfaces of an inductor 14. In this case, the effect of intercepting lines of magnetic force can be further increased.

(6) In each of the first and second embodiments, half-cut dicing is used to divide chips from the trenches 16 formed in advance, thereby preventing cracking and the like of these chips. However, the method is not limited to this half-cut dicing. For example, it is also possible to adhere the protective tape 17 to the first chip 10, grind the lower surface of the first chip 10, divide the first chip 10 together with the protective tape 17, and then adhere each first chip 10 to the second chip 20.

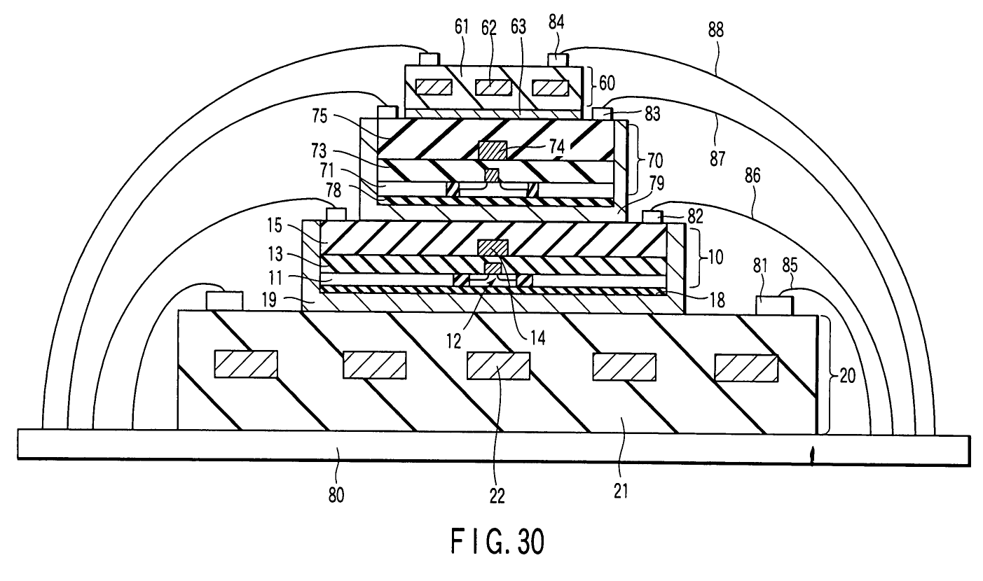

(7) Each of the first and second embodiments is explained by taking an SIP structure in which two chips are stacked as an example. However, it is of course also possible to stack three or more chips. For example, as shown in each of FIGS. 29 and 30, it is possible to stack four chips 20, 10, 60, and 70, form pads 81, 82, 83, and 84 on the chips 20, 10, 60, and 70, respectively, and bond the pads 81, 82, 83, and 84 to a package 80 by wires 85, 86, 87, and 88, respectively. In this structure, it is desirable to stack these chips on the package 80 in descending order of size (so as to form a pyramid-like shape).

In the structure shown in FIG. 29, chips having no inductors and chips having inductors are alternately stacked. That is, the chip 10 having an inductor 14 is stacked on the chip 20 having no inductor, the chip 60 having no inductor is stacked on the chip 10, and the chip 70 having an inductor 74 is stacked on the chip 60. A magnetic field generated from the inductor 14 toward the chips 20 and 60 is suppressed by shielding layers 19 and 63, respectively. Similarly, a magnetic field generated from the inductor 74 toward the chip 60 is suppressed by a shielding layer 79.

In the structure shown in FIG. 30, two chips having inductors are sandwiched between chips having no inductors. That is, the chip 10 having an inductor 14 is stacked on the chip 20 having no inductor, the chip 70 having an inductor 74 is stacked on the chip 10, and the chip 60 having no inductor is stacked on the chip 70. A magnetic field generated from the inductor 14 toward the chip 20 is suppressed by a shielding layer 19. Similarly, a magnetic field generated from the inductor 74 toward the chips 10 and 60 is suppressed by shielding layers 79 and 63, respectively.

Note that the chips 10 and 70 having the inductors 14 and 74 are chips having, e.g., logic circuits, and the chips 20 and 60 having no inductors are chips having, e.g., analog circuits.

(8) The shield layer 19 need not be formed by a magnetic material as long as it functions as a layer (magnetic shielding layer) which intercepts magnetism. For example, the shielding layer 19 may also be formed by a metal layer having a high resistance of, e.g., 500Ω or more. To increase the resistance of the shielding layer 19 made of a metal layer to 500Ω or more, it is possible to make the shielding layer 19 very thin, or select a high-resistance metal as the material of the shielding layer 19.

Additional advantages and modifications will readily occur to those skilled in the art. Therefore, the invention in its broader aspects is not limited to the specific details and representative embodiments shown and described herein. Accordingly, various modifications may be made without departing from the spirit and scope of the general inventive concept as defined by the appended claims and their equivalents.

1. A semiconductor device comprising:
a first chip having an inductor;
a second chip stacked on the first chip and having a conductive layer; and
a first magnetic shielding layer formed between the first and second chips.

2. The device according to claim 1, wherein
the first chip comprises:
a semiconductor substrate having upper and lower surfaces; and
the inductor formed on the upper surface of the semiconductor substrate, and
the first magnetic shielding layer is formed on the lower surface of semiconductor substrate.

3. The device according to claim 1, further comprising a second magnetic shielding layer formed on side surfaces of the first chip.

4. The device according to claim 1, wherein a width of the first magnetic shielding layer is not less than three times an outer diameter of the inductor.

5. The device according to claim 1, wherein an area of the first magnetic shielding layer is larger than an area in which the inductor is present.

6. The device according to claim 1, wherein the first magnetic shielding layer is formed of a magnetic material.

7. The device according to claim 1, wherein the first magnetic shielding layer is formed of a material selected from the group including of Ni, Fe, Co, and a magnetic material containing at least one of Ni, Fe, and Co.

8. The device according to claim 1, wherein the first magnetic shielding layer is formed of a material selected from the group including of a ferrite-based magnetic material and permalloy-based magnetic material.

9. The device according to claim 1, wherein
the first magnetic shielding layer is formed of an alloy of Fe and Ni, and
an Fe content of the alloy is not more than 20%.

10. The device according to claim 1, wherein
the first magnetic shielding layer is formed of an alloy of Fe and Ni, and
a film thickness of the first magnetic shielding layer is less than 50 nm.

11. The device according to claim 2, wherein a film thickness of the semiconductor substrate is smaller than an outer diameter of the inductor.

12. The device according to claim 1, wherein a film thickness of the first chip is smaller than an outer diameter of the inductor.

13. The device according to claim 2, further comprising an insulating film formed between the first magnetic shielding layer and the lower surface of the semiconductor substrate, and having a film thickness of not less than 3 nm.

14. The device according to claim 1, wherein
the first chip has a buried insulating film and semiconductor layer forming an SOI substrate, and
the first magnetic shielding layer is formed on the buried insulating film.

15. The device according to claim 1, further comprising an adhesive which adheres the first and second chips, and contains a magnetic material.

16. The device according to claim 1, further comprising a second magnetic shielding layer formed on a surface of the second chip, which faces the first chip.

17. The device according to claim 1, wherein the first magnetic shielding layer is partially formed to have a gap on a lower surface of the first chip.

18. The device according to claim 17, wherein a pad of the second chip is formed in the gap.

19. The device according to claim 1, further comprising a second magnetic shielding layer formed around the inductor.

20. The device according to claim 19, wherein the second magnetic shielding layer is formed on an upper surface and side surfaces of the inductor.
